(19) United States
(12) Patent Application Publication
(10) Pub. No.: US 2008/0054274 A1
(43) Pub. Date: Mar. 6, 2008

(54) Edge-emitting light-emitting diode

(75) Inventors: Ching-Huei Wu, San Chung City (TW); Ming-Shiun Wu, San Chung City (TW)

Correspondence Address: TROXELL LAW OFFICE PLLC;SUITE 1404, 5205 LEESBURG PIKE, FALLS CHURCH, VA, 22041, US

(73) Assignee: Unity Opto Technology Co., Ltd.

(21) Appl. No.: 11/512,402

(22) Filed: Aug. 30, 2006

(51) Int. Cl. H01L 33/00

(52) U.S. Cl. 257/81

(57) ABSTRACT

An edge-emitting light-emitting diode comprises a base, a frame, and at least two chips. The base has a recessed cup on the front side. The frame is fixed on the inside of the recessed cup. The chips are electrically connected to the frame inside the recessed cup. The frame has a plurality of bended pins extending therefrom. The bended pins are arranged interlacedly, symmetrically on the lateral surface of the base toward opposite directions. As a result, the edge-emitting light-emitting diode can be placed steadily.

### FIELD OF THE INVENTION

The present invention relates to an edge-emitting light-emitting diode that comprises a base, a frame, and at least two chips, wherein the frame has several bended pins arranged symmetrically on the base toward opposite directions to balance the base.

### BACKGROUND OF THE INVENTION

It is well known that the initial light-emitting diode is formed by mounting a chip on a recessed region of a frame and performing the follow-up die bonding, wire bonding and molding steps so as to form a single piece of light-emitting diode. This single piece of light-emitting diode is generally applied to outdoor information displays, traffic lights, and brake lights on automobiles.

Recently, the light-emitting diode is gradually adopted as a light source for use in a backlight module. As shown in FIG. 4, this conventional light-emitting diode has a base A having a recessed cup B on the front side. In addition, several chips C are embedded in the recessed cup B and electrically connected to a frame D, wherein the frame D has several bended pins E unidirectionally mounted on the lateral surface of the base A. Besides, the recessed cup B including the chips C and the frame D located therein are sealed by a gel F. As a result, the light beams, which are emitted from the chips C of the light emitting diode, can be mixed, and then gathered by the recessed cup B of the base A for outward projection via the opening of the recessed cup B so as to enhance the lighting effect.

The conventional light-emitting diode of the backlight module is capable of providing the lateral lighting. However, during the welding process, the unidirectionally-oriented bended pins make the base easy to tilt, which produces the unavoidable displacement. Thus, the lighting effect of the light-emitting diode is affected.

In view of the foregoing description, the present inventor makes diligent effort to disclose an edge-emitting light-emitting diode to overcome the conventional drawbacks and limitations.

### SUMMARY OF THE INVENTION

It is a main object of the present invention to provide an edge-emitting light-emitting diode, which comprises a base, a frame, and at least two chips, wherein the frame has several pins arranged symmetrically on the base toward opposite directions to allow the edge-emitting light-emitting diode to be placed steadily.

In order to achieve the above-mentioned objects, an edge-emitting light-emitting diode of the present invention comprises a base, a frame, and at least two chips. The base has a recessed cup on the front side. The frame is fixedly mounted on the inside of the recessed cup. The chips are electrically connected to the frame inside the recessed cup. The frame has a plurality of bended pins extending therefrom. The bended pins are arranged interlacedly, symmetrically on the lateral surface of the base toward opposite directions. As a result, the edge-emitting light-emitting diode can be placed steadily.

The aforementioned objects and advantages of the present invention will be readily clarified in the description of the preferred embodiments and the enclosed drawings of the present invention.

### BRIEF DESCRIPTION OF THE DRAWINGS

FIG. 1 is an elevational diagram of the present invention.

FIG. 2 shows a cross-sectional view taken along line AA of FIG. 1.

FIG. 3 shows a front view of FIG. 1.

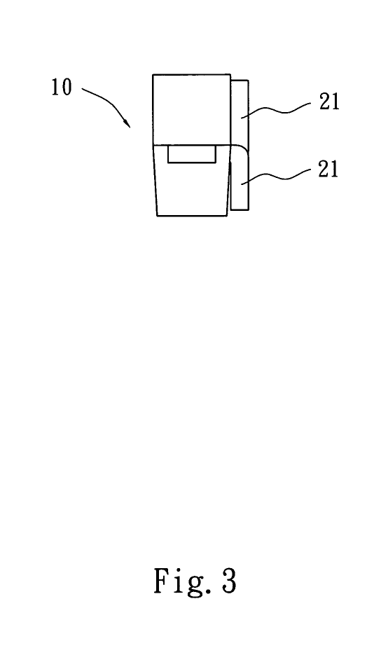

FIG. 4 is an elevational diagram of the prior art.

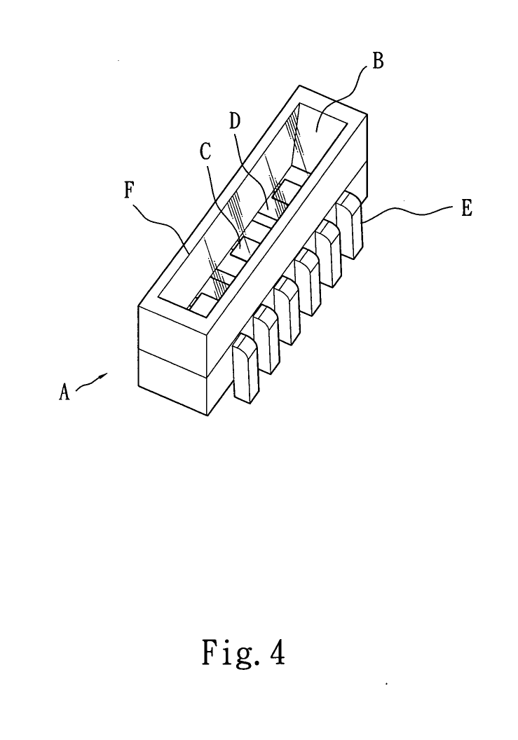

### DETAILED DESCRIPTION OF THE PREFERRED EMBODIMENT

The objects, features, advantages, and benefits of the invention will become apparent in the following description taken in conjunction with the foregoing drawings.

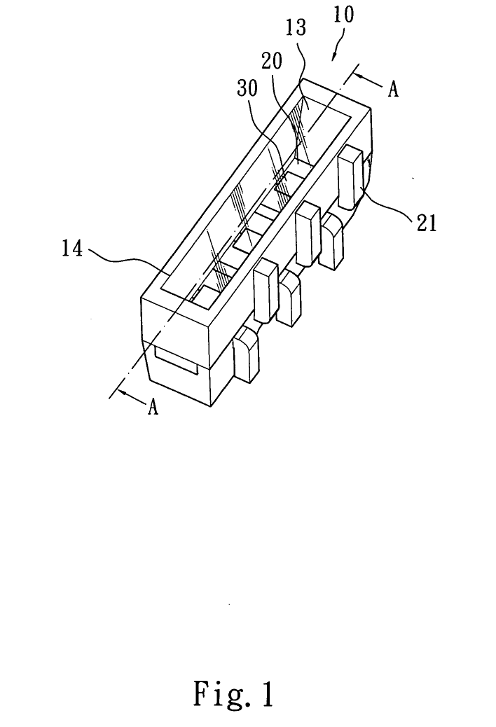

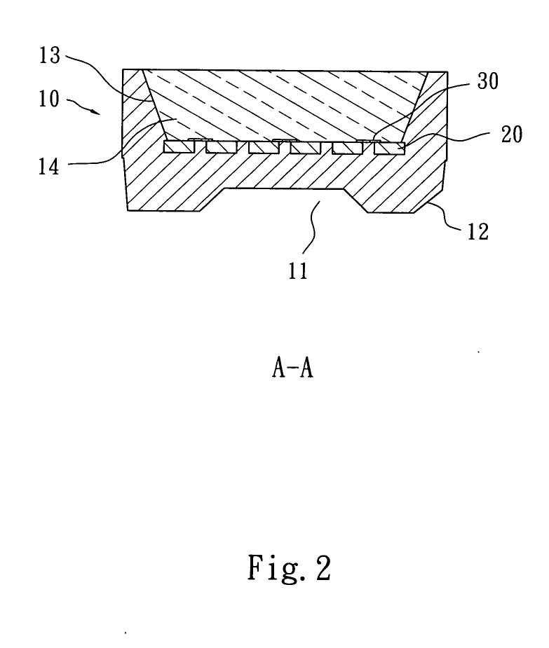

Referring to FIGS. 1 and 2, an edge-emitting light-emitting diode of the present invention comprises a base 10 having a recessed cup 13 on the front side. A frame 20 is fixedly mounted on the inside of the recessed cup 13. At least two chips 30 are mounted on the frame 20 by a flip-chip bonding method. In addition, a gel 14 is filled into the recessed cup 13. Besides, several bended pins 21 are extended from one side of the frame 20, and these bended pins 21 are interlacedly, symmetrically arranged on the lateral surface of the base 10 toward opposite directions. In addition, the base 10 has a recessed region 11 on the rear center and a bevel edge 12 on the backside.

During the welding process of the aforesaid structure of the present invention, the bended pins 21 that locate interlacedly, symmetrically on the lateral surface of the base 10 are helpful to balance the base 10, thereby preventing the base 10 from lateral tilt so as to facilitate the welding process. As a result, after the welding process is completed, the chips 30, which are located on the frame 20 of the base 10 for emitting the light beams, are prevented from displacement. Accordingly, the steadiness of the whole structure can be maintained and the lighting effect in the correct direction can be improved.

In accordance with the foregoing description, the present invention has the following advantages:

During the welding process, the bended pins that locate symmetrically on the lateral surface of the base are helpful to balance the base, thereby preventing the base from lateral tilt so as to facilitate the welding process. Accordingly, the steadiness of the whole structure can be maintained and the lighting effect in the correct direction can be improved.

In summary, the present invention indeed achieves the expected objects by disclosing an easy-to-manufacture edge-emitting light-emitting diode. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. An edge-emitting light-emitting diode comprising:
a base having a recessed cup on the front side thereof;
a frame fixed on the inside of said recessed cup and having a plurality of bended pins extending therefrom and arranged interlacedly, symmetrically on the lateral surface of said base toward opposite directions; and
at least two chips electrically connected to said frame inside said recessed cup.

2. The edge-emitting light-emitting diode of claim 1, wherein said at least two chips are flip-chip bonded chips.
